(19) United States
(12) Patent Application Publication
(10) Pub. No.: US 2024/0369931 A1
(43) Pub. Date: Nov. 7, 2024

(54) METHOD OF MANUFACTURING SEMICONDUCTOR SUBSTRATE, METHOD FOR FORMING RESIST UNDERLAYER FILM, AND CLEANING LIQUID

(71) Applicant: JSR CORPORATION, Tokyo (JP)

(72) Inventors: Yuki OZAKI, Tokyo (JP); Hiroki HIRABAYASHI, Tokyo (JP); Kengo HIRASAWA, Tokyo (JP); Ryuichi SERIZAWA, Tokyo (JP)

(73) Assignee: JSR CORPORATION, Tokyo (JP)

(21) Appl. No.: 18/769,554

(22) Filed: Jul. 11, 2024

Related U.S. Application Data
(63) Continuation-in-part of application No. PCT/JP2023/000437, filed on Jan. 11, 2023.

(30) Foreign Application Priority Data
Jan. 14, 2022 (JP) 2022-004064

(51) Int. Cl. G03F 7/11; C11D 7/26; C11D 7/50; G03F 7/004

(52) U.S. Cl. CPC G03F 7/11; C11D 7/265; C11D 7/5009; C11D 7/5022; G03F 7/0043

(57) ABSTRACT

A method for manufacturing a semiconductor substrate, includes: applying a composition for forming a resist underlayer film directly or indirectly to a substrate to form a resist underlayer film; cleaning a periphery of the substrate with a cleaning liquid; and after cleaning the periphery, forming a resist pattern directly or indirectly on the resist underlayer film. The composition for forming a resist underlayer film includes: a metal compound; and a solvent. The cleaning liquid includes an organic acid.

### CROSS-REFERENCE TO RELATED APPLICATIONS

The present application is a continuation-in-part application of International Patent Application No. PCT/JP2023/000437 filed Jan. 11, 2023, which claims priority to Japanese Patent Application No. 2022-004064 filed Jan. 14, 2022. The contents of these applications are incorporated herein by reference in their entirety.

### BACKGROUND OF THE DISCLOSURE

### Technical Field

The present disclosure relates to a method for manufacturing a semiconductor substrate, a method for forming a resist underlayer films, and a cleaning liquid.

### Background Art

In the manufacture of semiconductor substrates and the like, a metal hard mask composition, which is a resist underlayer film, has been proposed (see JP-A 2013-185155). For example, Clean Track (manufactured by Tokyo Electron Ltd.) is used as an equipment for manufacturing semiconductor substrates and the like. EBR is a process in which a film is formed on a substrate (wafer) by spin coating, followed by cleaning with a cleaning liquid to remove the film at the edges (periphery) of the substrate. This equipment automatically transports the substrate, but EBR must be performed to prevent contamination of the tweezers that hold the substrate; if the substrate edges cannot be cleaned by EBR, the tweezers may become contaminated, causing defects and lowering the device yield rate. When manufacturing a semiconductor substrate, and the like., it is generally required that the substrate edges can be cleaned by EBR. A mixture of propylene glycol monomethyl ether acetate and propylene glycol monoethyl ether (30:70 by mass) is widely used as a cleaning liquid in the EBR process for resist films, silicon-containing films, and organic underlayer films.

### SUMMARY

According to an aspect of the present disclosure, a method for manufacturing a semiconductor substrate, includes: applying a composition for forming a resist underlayer film directly or indirectly to a substrate to form a resist underlayer film; cleaning a periphery of the substrate with a cleaning liquid; and after cleaning the periphery, forming a resist pattern directly or indirectly on the resist underlayer film. The composition for forming a resist underlayer film includes: a metal compound (hereinafter, may be referred to as “compound [A]”); and a solvent (hereinafter, may be referred to as “solvent [B]”). The cleaning liquid includes an organic acid (hereinafter, may be referred to as “organic acid [E]).

According to another aspect of the present disclosure, a method of forming a resist underlayer film, includes: applying a composition for forming a resist underlayer film directly or indirectly to a substrate to form a resist underlayer film; and cleaning a periphery of the substrate with a cleaning liquid. The composition for forming a resist underlayer film includes: a metal compound; and a solvent. The cleaning liquid includes an organic acid.

According to a further aspect of the present disclosure, a cleaning liquid includes an organic acid. The cleaning liquid is suitable for a method for manufacturing a semiconductor substrate, the method including applying a composition for forming a resist underlayer film directly or indirectly to a substrate to form a resist underlayer film, and cleaning the periphery of the substrate with the cleaning liquid. The composition for forming a resist underlayer film includes: a metal compound; and a solvent.

### DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

Cleaning liquid is required to remove metal hard masks at the periphery of the substrate, etc. In addition, when a multilayer resist process is performed in a single device, waste liquid from multiple processes are often discharged through the same pipe, so the cleaning liquid is required to have drainage stability to control unintended events such as metal deposition in the pipe due to interference with other waste liquid.

An embodiment of the method for manufacturing a semiconductor substrate of the present disclosure can efficiently manufacture semiconductor substrates having high quality because the periphery of the substrate is cleaned using a cleaning liquid with excellent cleanability and drainage stability. According to an embodiment of the method for forming the resist underlayer film, the desired resist underlayer film can be formed efficiently because the cleaning liquid with excellent cleanability and drainage stability is used. An embodiment of the cleaning liquid is excellent in both cleanability and drainage stability. Therefore, they can be suitably used in the manufacture of semiconductor devices, etc., which are expected to be further miniaturized in the future.

The following is a detailed description of the method for manufacturing a semiconductor substrate, a method for forming a resist underlayer film, and cleaning liquid for each of the embodiments of the disclosure. Combinations of suitable embodiments are also preferred.

### <<Method for Manufacturing Semiconductor Substrate>>

The method for manufacturing a semiconductor substrate, includes applying a composition for forming a resist underlayer film (hereinafter also referred to as “composition”) directly or indirectly to a substrate to form a resist underlayer film (hereinafter also referred to as “applying step”), cleaning the periphery of the substrate with a cleaning liquid (hereinafter also referred to as “cleaning step”), after cleaning the periphery, forming a resist pattern directly or indirectly on the resist underlayer film (hereinafter also referred to as “resist pattern forming step”). Furthermore, it is preferred that the method for manufacturing a semiconductor substrate includes forming a pattern on the resist underlayer film by etching using the resist pattern as a mask (hereinafter also referred to as the “etching step”).

The periphery of the substrate is, for example, the outer portion of the substrate whose length from the outer edge of the substrate to the center of the substrate is 3.0 cm or less. The length from the outer edge of the substrate to the center of the substrate can be 2.0 cm, 1.0 cm, 0.5 cm, or 0.2 cm.

If necessary, the method for manufacturing a semiconductor substrate may further include, before the resist pattern forming step, forming an organic underlayer film directly or indirectly on the substrate having a resist underlayer film formed in the applying step (hereinafter also referred to as an “organic underlayer film forming step).

If necessary, the method for manufacturing a semiconductor substrate may further include, before the resist pattern forming step, forming a silicon-containing film directly or indirectly on the substrate having a resist underlayer film formed in the applying step (hereinafter also referred to as a “silicon-containing film forming step).

Hereinafter, description will be made to the composition for forming a resist underlayer film and cleaning liquid that are used for the method for manufacturing a semiconductor substrate, and respective steps in the case of including an organic underlayer film forming step and a silicon-containing film forming step, which are optional steps.

### <Composition for Forming Resist Underlayer Film>

The composition contains the compound [A] and the solvent [B]. The composition may contain other optional ingredients to the extent that the effect of the invention is not impaired.

### [Compound [A] ]

The compound [A] is a compound including a metal atom and an oxygen atom. Examples of the metal atom constituting the compound [A] include metal atoms of Groups 3 to 16 of the periodic table (excluding silicon atom). The compound [A] may have one kind or two or more kinds of metal atom.

Examples of Group 3 metal atom include scandium, yttrium, lanthanum, and cerium;
examples of Group 4 metal atom include titanium, zirconium, and hafnium;
examples of Group 5 metal atom include vanadium, niobium, and tantalum;
examples of Group 6 metal atom include chromium, molybdenum, and tungsten;
examples of Group 7 metal atom include manganese and rhenium; examples of Group 8 metal atom include iron, ruthenium, and osmium;
examples of Group 9 metal atom include cobalt, rhodium, and iridium;
examples of Group 10 metal atom include nickel, palladium, and platinum;
examples of Group 11 metal atom include copper, silver, and gold;
examples of Group 12 metal atom include zinc, cadmium, and mercury;
examples of Group 13 metal atom include aluminum, gallium, and indium;
examples of Group 14 metal atom include germanium, tin, and lead;
examples of Group 15 metal atom include antimony and bismuth; and
examples of Group 16 metal atom include tellurium.

As the metal atom constituting the compound [A], metal atoms of Group 3 to Group 16 are preferable, metal atoms of Group 4 to Group 14 are more preferable, metal atoms of Group 4, Group 5, and Group 14 are still more preferable, and metal atoms of Group 4 are particularly preferable. Specifically, titanium, zirconium, hafnium, tantalum, tungsten, tin, or a combination thereof is more preferable.

As the component (hereinafter also referred to as “compound [x]”) other than the metal atom constituting the compound [A], an organic acid (hereinafter also referred to as “organic acid [a]”), a hydroxy acid ester, a β-diketone, an α,α-dicarboxylic acid ester, and an amine compound are preferable. Herein, the “organic acid” refers to any organic compound that exhibits acidity, and the “organic compound” refers to any compound having at least one carbon atom.

Examples of the organic acid [a] include carboxylic acids, sulfonic acids, sulfinic acids, organic phosphinic acids, organic phosphonic acids, phenols, enols, thiols, acid imides, oximes, and sulfonamides.

Examples of the carboxylic acids include monocarboxylic acids such as formic acid, acetic acid, propionic acid, butanoic acid, pentanoic acid, hexanoic acid, heptanoic acid, octanoic acid, nonanoic acid, decanoic acid, 2-ethylhexanoic acid, oleic acid, acrylic acid, methacrylic acid, trans-2,3-dimethylacrylic acid, stearic acid, linoleic acid, linolenic acid, arachidonic acid, salicylic acid, benzoic acid, p-aminobenzoic acid, monochloroacetic acid, dichloroacetic acid, trichloroacetic acid, trifluoroacetic acid, pentafluoropropionic acid, gallic acid, and shikimic acid; dicarboxylic acids such as oxalic acid, malonic acid, maleic acid, methylmalonic acid, fumaric acid, adipic acid, sebacic acid, phthalic acid, and tartaric acid; and carboxylic acids having three or more carboxy groups such as citric acid.

Examples of the sulfonic acids include benzenesulfonic acid and p-toluenesulfonic acid.

Examples of the sulfinic acids include benzenesulfinic acid and p-toluenesulfinic acid.

Examples of the organic phosphinic acids include diethylphosphinic acid, methylphenylphosphinic acid, and diphenylphosphinic acid.

Examples of the organic phosphonic acids include methylphosphonic acid, ethylphosphonic acid, t-butylphosphonic acid, cyclohexylphosphonic acid, and phenylphosphonic acid.

Examples of the phenols include monohydric phenols such as phenol, cresol, 2,6-xylenol, and naphthol;
dihydric phenols such as catechol, resorcinol, hydroquinone, and 1,2-naphthalenediol; and
trihydric or higher phenols such as pyrogallol and 2,3,6-naphthalenetriol.

Examples of the enols include 2-hydroxy-3-methyl-2-butene and 3-hydroxy-4-methyl-3-hexene.

Examples of the thiols include mercaptoethanol and mercaptopropanol.

Examples of the acid imides include carboxylic acid imides such as maleimide and succinimide, and sulfonic acid imides such as di(trifluoromethanesulfonic acid) imide and di(pentafluoroethanesulfonic acid) imide.

Examples of the oximes include aldoximes such as benzaldoxime and salicylaldoxime, and ketoximes such as diethylketoxime, methylethylketoxime, and cyclohexanone oxime.

Examples of the sulfonamides include methylsulfonamide, ethylsulfonamide, benzenesulfonamide, and toluenesulfonamide.

As the organic acid [a], carboxylic acids are preferable, monocarboxylic acids are more preferable, and methacrylic acid and benzoic acid are still more preferable.

Examples of the hydroxy acid esters include glycolic acid esters, lactic acid esters, 2-hydroxycyclohexane-1-carboxylic acid esters, and salicylic acid esters.

Examples of the B-diketones include 2,4-pentanedione, 3-methyl-2,4-pentanedione, and 3-ethyl-2,4-pentanedione.

Examples of the B-ketoesters include acetoacetic acid esters, a-alkyl-substituted acetoacetic acid esters, B-ketopentanoic acid esters, benzoylacetic acid esters, and 1,3-acetonedicarboxylic acid esters.

Examples of the amine compounds include diethanolamine and triethanolamine.

As the compound [A], metal compounds composed of a metal atom and an organic acid [a] are preferable, metal compounds composed of a Group 4, Group 5 or Group 14 metal atom and a carboxylic acid are more preferable, and metal compounds composed of titanium, zirconium, hafnium, tantalum, tungsten or tin and methacrylic acid or benzoic acid are still more preferable. The form of the organic acid [a] included in the compound [A] also includes an organic acid anion obtained by removing a hydrogen ion from the organic acid [a].

The compound [A] may include one or two or more of the metal compound.

The compound [A] may include one or two or more of the organic acid [a].

The lower limit of the content ratio of the compound [A] accounting for in all components contained in the composition is preferably 2% by mass, more preferably 4% by mass, and still more preferably 6% by mass. The upper limit of the content ratio is preferably 30% by mass, more preferably 20% by mass, and still more preferably 15% by mass.

[Method for synthesizing compound [A] ] The compound [A] can be synthesized by, for example, a method of performing a hydrolysis-condensation reaction using a metal-containing compound (hereinafter also referred to as “metal-containing compound [b]”), a method of performing a ligand substitution reaction using a metal-containing compound [b], or the like. Herein, the “hydrolysis-condensation reaction” refers to a reaction in which the hydrolyzable group of the metal-containing compound [b] is hydrolyzed to be converted into —OH, and the resulting two —OH groups are dehydration-condensed to form —O—.

(Metal-containing compound [b])

The metal-containing compound [b] is a metal compound (b1) having a hydrolyzable group, a hydrolysate of a metal compound (b1) having a hydrolyzable group, a hydrolysis-condensate of a metal compound (b1) having a hydrolyzable group, or a combination thereof. The metal compound (b1) may be used singly or two or more thereof may be used in combination.

Examples of the hydrolyzable group include a halogen atom, an alkoxy group, and an acyloxy group.

Examples of the halogen atom include a fluorine atom, a chlorine atom, a bromine atom, and an iodine atom.

Examples of the alkoxy group include a methoxy group, an ethoxy group, a n-propoxy group, an isopropoxy group, and a n-butoxy group.

Examples of the acyloxy group include an acetoxy group, an ethylyloxy group, a propionyloxy group, a butyryloxy group, a t-butyryloxy group, a t-amylyloxy group, an n-hexanecarbonyloxy group, and an n-octanecarbonyloxy group.

As the hydrolyzable group, an alkoxy group and an acyloxy group are preferable, and an isopropoxy group and an acetoxy group are more preferable.

When the metal-containing compound [b] is a hydrolysis-condensate of a metal compound (b1), the hydrolysis-condensate of the metal compound (b1) may be a hydrolysis-condensate of the metal compound (b1) having a hydrolyzable group and a compound containing a metalloid atom as long as the effect of the present invention is not impaired. That is, the hydrolysis-condensate of the metal compound (b1) may contain a metalloid atom as long as the effect of the present invention is not impaired. Examples of the metalloid atom include silicon, boron, germanium, antimony, and tellurium. The content of the metalloid atom in the hydrolysis-condensate of the metal compound (b1) is usually less than 50 atom % based on the total of the metal atom and the metalloid atom in the hydrolysis-condensate.

The upper limit of the content of the metalloid atom is preferably 30 atom %, more preferably 10 atom % based on the total of the metal atom and the metalloid atom in the hydrolysis-condensate.

Examples of the metal compound (b1) include a compound represented by formula (a) (hereinafter also referred to as “compound [m]”).

[Formula 7]

LₐMY_{b} (α)

In the formula (α), M is a metal atom. L is a ligand. a is an integer of 0 to 2. When a is 2, a plurality of L's are the same or different. Y is a hydrolyzable group selected from among a halogen atom, an alkoxy group, and an acyloxy group. b is an integer of 2 to 6. The plurality of Y's may be the same or different. Note that L is a ligand that does not correspond to Y.

Examples of the metal atom represented by M include metal atoms the same as those disclosed as examples of the metal atom constituting the metal compound contained in the compound [A].

Examples of the ligand represented by L include a monodentate ligand and a multidentate ligand.

Examples of the monodentate ligand include a hydroxo ligand, a carboxy ligand, an amide ligand, and ammonia.

Examples of the amide ligand include an unsubstituted amide ligand (NH₂), a methylamide ligand (NHMe), a dimethylamide ligand (NMe₂), a diethylamide ligand (NEt₂), and a dipropylamide ligand (NPr₂).

Examples of the multidentate ligand include hydroxy acid esters, β-diketones, β-ketoesters, β-dicarboxylic acid esters, hydrocarbons having a n bond, and diphosphines.

Examples of the hydroxy acid esters include glycolic acid esters, lactic acid esters, 2-hydroxycyclohexane-1-carboxylic acid esters, and salicylic acid esters.

Examples of the β-diketones include 2,4-pentanedione, 3-methyl-2,4-pentanedione, and 3-ethyl-2,4-pentanedione.

Examples of the β-ketoesters include acetoacetic acid esters, α-alkyl-substituted acetoacetic acid esters, β-ketopentanoic acid esters, benzoylacetic acid esters, and 1,3-acetonedicarboxylic acid esters.

Examples of the β-dicarboxylic acid esters include malonic diesters, α-alkyl-substituted malonic diesters, α-cycloalkyl-substitutedmalonic diesters, and a-aryl-substituted malonic diesters.

Examples of the hydrocarbons having a n bond include
chain olefins such as ethylene and propylene;
cyclic olefins such as cyclopentene, cyclohexene, and norbornene;
chain dienes such as butadiene and isoprene;
cyclic dienes such as cyclopentadiene, methylcyclopentadiene, pentamethylcyclopentadiene, cyclohexadiene, and norbornadiene; and
aromatic hydrocarbons such as benzene, toluene, xylene, hexamethylbenzene, naphthalene, and indene.

Examples of the diphosphines include 1,1-bis(diphenylphosphino)methane, 1,2-bis(diphenylphosphino)ethane, 1,3-bis(diphenylphosphino)propane, 2,2′-bis(diphenylphosphino)-1,1′-binaphthyl, and 1,1′-bis(diphenylphosphino)ferrocene.

Examples of the halogen atom represented by Y include a fluorine atom, a chlorine atom, a bromine atom, and an iodine atom.

Examples of the alkoxy group represented by Y include a methoxy group, an ethoxy group, a propoxy group, and a butoxy group.

Examples of the acyloxy group represented by Y include an acetoxy group, an ethylyloxy group, a butyryloxy group, a t-butyryloxy group, a t-amylyloxy group, an n-hexanecarbonyloxy group, and an n-octanecarbonyloxy group.

As Y, an alkoxy group and an acyloxy group are preferable, and an isopropoxy group and an acetoxy group are more preferable.

As b, 3 and 4 are preferable, and 4 is more preferable.

As the metal-containing compound [b], metal alkoxides subjected to neither hydrolysis nor hydrolysis-condensation and metal acyloxides subjected to neither hydrolysis nor hydrolysis-condensation are preferable.

Examples of the metal-containing compound [b] include zirconium tetra-n-butoxide, zirconium tetra-n-propoxide, zirconium tetraisopropoxide, hafnium tetraethoxide, indium triisopropoxide, hafnium tetraisopropoxide, hafnium tetra-n-propoxide, hafnium tetra-n-butoxide, tantalum pentaethoxide, tantalum penta-n-butoxide, tungsten pentamethoxide, tungsten penta-n-butoxide, tungsten hexaethoxide, tungsten hexa-n-butoxide, iron chloride, zinc diisopropoxide, zinc acetate dihydrate, tetrabutyl orthotitanate, titanium tetra-n-butoxide, titanium tetra-n-propoxide, zirconium di-n-butoxide bis(2,4-pentanedionate), titanium tri-n-butoxide stearate, bis(cyclopentadienyl)hafnium dichloride, bis(cyclopentadienyl)tungsten dichloride, diacetato[(S)-(-)-2,2′-bis(diphenylphosphino)-1,1′-binaphthyl]ruthenium, dichloro[ethylenebis(diphenylphosphine)]cobalt, titanium butoxide oligomer, aminopropyltrimethoxytitanium, aminopropyltriethoxyzirconium, 2-(3,4-epoxycyclohexyl)ethyltrimethoxyzirconium, γ-glycidoxypropyltrimethoxyzirconium, 3-isocyanopropyltrimethoxyzirconium, 3-isocyanopropyltriethoxyzirconium, triethoxymono(acetylacetonato)titanium, tri-n-propoxymono(acetylacetonato)titanium, tri-isopropoxymono(acetylacetonato)titanium, triethoxymono(acetylacetonato)zirconium, tri-n-propoxymono(acetylacetonato)zirconium, tri-isopropoxymono(acetylacetonato)zirconium, diisopropoxybis(acetylacetonato)titanium, di-n-butoxybis(acetylacetonato)titanium, di-n-butoxybis(acetylacetonato)zirconium, tri(3-methacryloxypropyl)methoxyzirconium, tri(3-acryloxypropyl)methoxyzirconium, tin tetraisopropoxide, tin tetra-n-butoxide, lanthanum oxide, and yttrium oxide.

Among them, metal alkoxides and metal acyloxides are preferable, metal alkoxides are more preferable, and alkoxides of titanium, zirconium, hafnium, tantalum, tungsten, and tin are still more preferable.

When an organic acid is used for the synthesis of the compound [A], the lower limit of the amount of the organic acid used is preferably 1 mol, more preferably 2 mol, per mole of the metal-containing compound [b]. On the other hand, the upper limit of the amount of the organic acid used is preferably 6 mol, more preferably 5 mol, per mole of the metal-containing compound [b].

In the synthesis reaction of the compound [A], in addition to the metal compound (b1) and the organic acid [a], a compound capable of serving as a multidentate ligand represented by L in the compound of the formula (a), a compound capable of serving as a bridging ligand, or the like may be added. Examples of the compound capable of serving as a bridging ligand include compounds having a plurality of hydroxy groups, isocyanate groups, amino groups, ester groups, or amide groups.

Examples of the method of performing the hydrolysis-condensation reaction using the metal-containing compound [b] include a method of subjecting the metal-containing compound [b] to a hydrolysis-condensation reaction in a solvent containing water. In this case, another compound having a hydrolyzable group may be added, as necessary. The lower limit of the amount of water used in the hydrolysis-condensation reaction is preferably 0.2 times mol, more preferably 1 time mol, and still more preferably 3 times mol, in the number of moles, based on the hydrolyzable group of the metal-containing compound [b] and the like. The upper limit of the amount of water is preferably 20 times mol, more preferably 15 times mol, and still more preferably 10 times mol.

Examples of the method of performing the ligand substitution reaction using the metal-containing compound [b] include a method involving mixing the metal-containing compound [b] and the organic acid [a]. In this case, the metal-containing compound [b] and the organic acid [a] may be mixed in a solvent, or may be mixed without using a solvent. In the mixing, a base such as triethylamine may be added, as necessary. The addition amount of the base is, for example, 1 part by mass or more and 200 parts by mass or less based on 100 parts by mass of the total use amount of the metal-containing compound [b] and the organic acid [a].

The solvent to be used in the synthesis reaction of the compound [A] (hereinafter also referred to as “solvent [d]”) is not particularly limited, and for example, the same solvents as those disclosed as examples of the solvent [B] described later can be used. Among them, alcohol-based solvents, ether-based solvents, ester-based solvents, and hydrocarbon-based solvents are preferable, alcohol-based solvents, ether-based solvents, and ester-based solvents are more preferable, monoalcohol-based solvents, polyhydric alcohol partial ether-based solvents, and polyhydric alcohol partial ether carboxylate-based solvents are still more preferable, and monoalcohol-based solvents having one to four carbon atoms, and propylene glycol monoethyl ether are particularly preferable.

When the solvent [d] is used in the synthesis reaction of the compound [A], the solvent used may be removed after the reaction, but may be used as it is as the solvent [B] of the composition for forming a resist underlayer film without being removed after the reaction.

### [Solvent [B] ]

The solvent [B] is not particularly limited as long as it is a solvent capable of dissolving or dispersing at least the compound [A], other optional components, and the like. The composition may contain one or two or more of the solvent [B].

Examples of the solvent [B] include organic solvents. Examples of the organic solvent include alcohol-based solvents, ketone-based solvents, ether-based solvents, ester-based solvents, nitrogen-containing solvents, and sulphur-containing solvents.

Examples of the alcohol-based solvents include monoalcohol-based solvents such as methanol, ethanol, n-propanol, isopropanol, and 1-butanol, and polyhydric alcohol-based solvents such as ethylene glycol, 1,2-propylene glycol, triethylene glycol, and tripropylene glycol.

Examples of the ketone-based solvents include chain ketone-based solvents such as methyl ethyl ketone, methyl isobutyl ketone, and 2-heptanone; and cyclic ketone-based solvents such as cyclohexanone.

Examples of the ether-based solvents include chain ether-based solvents such as n-butyl ether; polyhydric alcohol ether-based solvents such as cyclic ether-based solvents such as tetrahydrofuran and 1,4-dioxane; and polyhydric alcohol partial ether-based solvents such as propylene glycol monoethyl ether, tripropylene glycol monomethyl ether, and tetraethylene glycol monomethyl ether.

Examples of the ester-based solvents include carbonate-based solvents such as diethyl carbonate; acetic acid monoacetate ester-based solvents such as methyl acetate, ethyl acetate, and butyl acetate; lactone-based solvents such as γ-butyrolactone; polyhydric alcohol partial ether carboxylate-based solvents such as diethylene glycol monomethyl ether acetate and propylene glycol monomethyl ether acetate; and lactic acid ester-based solvents such as methyl lactate and ethyl lactate.

Examples of the nitrogen-containing solvents include chain nitrogen-containing solvents such as N,N-dimethylacetamide, and cyclic nitrogen-containing solvents such as N-methylpyrrolidone.

Examples of the sulphur-containing solvents include chain sulphur-containing solvents such as dimethylsulphone and dimethylsulphoxide, and cyclic sulphur-containing solvents such as sulfolane.

Additional examples include aromatic hydrocarbon-based solvents such as toluene, xylene, and mesitylene.

As the solvent [B], an ether-based solvent, an ester-based solvent ketone-based solvents or a combination thereof are preferable, a polyhydric alcohol partial ether-based solvent, an acetic acid monoacetate ester-based solvents, a polyhydric alcohol partial ether carboxylate-based solvent, chain ketone-based solvents or a combination thereof are more preferable, and propylene glycol monoethyl ether, butyl acetate, propylene glycol monomethyl ether acetate, 2-heptanone or a combination thereof is still more preferable.

The lower limit of the content of the solvent [B] accounting for in the total amount of the compound [A] and the solvent [B] is more preferably 50 mass %, preferably 60 mass %, and more preferably 70 mass %. The upper limit of the content is preferably 99% by mass, more preferably 95% by mass, and still more preferably 90% by mass. Owing to that the content of the solvent [B] is adjusted within the above range, the preparation of the composition can be facilitated, and the coatability can be improved.

### [Other Optional Components]

The composition may contain, for example, an acid generating agent, a macromolecular additive, a polymerization inhibitor, a surfactant, etc. as components other than those described above.

When the composition contains other optional components, the content of the other optional components in the composition can be appropriately determined according to the type, function, and so on of the other optional components to be used.

The acid generating agent is a compound that generates an acid by radiation irradiation and/or heating. The composition may contain one or two or more of the acid generating agent.

Examples of the acid generating agent include an onium salt compound and an N-sulfonyloxyimide compound.

When the composition contains a macromolecular additive, the composition can further enhance the coatability to a substrate and an organic underlayer film and the continuity of a film. The composition may contain one or two or more of the macromolecular additive.

Examples of the macromolecular additive include (poly)oxyalkylene-based macromolecular compounds, fluorine-containing macromolecular compounds, and non-fluorine-containing macromolecular compounds.

Examples of the (poly)oxyalkylene-based macromolecular compounds include: polyoxyalkylenes such as a (poly)oxyethylene-(poly)oxypropylene adduct; (poly)oxyalkyl ethers such as diethylene glycol heptyl ether, polyoxyethylene oleyl ether, polyoxypropylene butyl ether, polyoxyethylene polyoxypropylene-2-ethyl hexyl ether, and an adduct of oxyethylene-oxypropylene to a higher alcohol having 12 to 14 carbon atoms; (poly)oxyalkylene (alkyl) aryl ethers such as polyoxypropylene phenyl ether and polyoxyethylene nonyl phenyl ether; acetylene ethers obtained by addition polymerization of acetylene alcohol and an alkylene oxide, such as 2,4,7,9-tetramethyl-5-decyne-4,7-diol, 2,5-dimethyl-3-hexyne-2,5-diol, and 3-methyl-1-butyn-3-ol; (poly) oxyalkylene fatty acid esters such as diethylene glycol oleic acid ester, diethylene glycol lauric acid ester, and ethylene glycol distearic acid ester; (poly) oxyalkylene sorbitan fatty acid esters such as polyoxyethylene sorbitan monolauric acid ester and polyoxyethylene sorbitan trioleic acid ester; (poly)oxyalkylene alkyl (aryl) ether sulfuric acid ester salts such as polyoxypropylene methyl ether sodium sulfate and polyoxyethylene dodecyl phenol ether sodium sulfate; (poly)oxyalkylene alkyl phosphoric acid esters such as (poly)oxyethylene stearyl phosphoric acid ester; and (poly)oxyalkylene alkyl amines such as polyoxyethylene lauryl amine.

Examples of the fluorine-containing macromolecular compounds include compounds disclosed in JP-A-2011-89090. Examples of the fluorine-containing macromolecular compounds include compounds containing a repeating unit derived from a (meth) arylate compound having a fluorine atom and a repeating unit derived from a (meth)acrylate compound having two or more (preferably five or more) alkyleneoxy groups (preferably an ethyleneoxy group, a propyleneoxy group).

Examples of the non-fluorine-containing macromolecular compounds include compounds containing one kind or two or more kinds of repeating units derived from a (meth)acrylate monomer such as a linear or branched alkyl (meth)acrylate such as lauryl (meth)acrylate, 2-ethylhexyl (meth)acrylate, n-butyl (meth)acrylate, t-butyl (meth)acrylate, isooctyl (meth)acrylate, isostearyl (meth)acrylate, or isononyl (meth)acrylate, an alkoxyethyl (meth)acrylate such as methoxyethyl (meth)acrylate, an alkylene glycol di(meth)acrylate such as ethylene glycol di(meth)acrylate or 1,3-butylene glycol di(meth)acrylate, a hydroxyalkyl (meth)acrylate such as 2-hydroxyethyl (meth)acrylate, 2-hydroxypropyl (meth)acrylate, 2-hydroxybutyl (meth)acrylate, or 4-hydroxybutyl (meth)acrylate, dicyclopentenyloxyethyl (meth)acrylate, or nonylphenoxy polyethylene glycol (having a —(CH₂CH₂O)ₙ— structure, n=1 to 17) (meth)acrylate.

When the composition contains a polymerization inhibitor, the storage stability of the composition can be enhanced. The composition may contain one or two or more of the polymerization inhibitor.

Examples of the polymerization inhibitor include hydroquinone compounds such as 4-methoxyphenol and 2,5-di-tert-butylhydroquinone, and nitroso compounds such as N-nitrosophenylhydroxylamine and aluminum salts thereof.

When the composition contains a surfactant, the coatability to a substrate or an organic underlayer film and the continuity of a film can be further enhanced. The composition may contain one or two or more of the surfactant.

Examples of a commercially-available product of the surfactant include “Newcol 2320”, “Newcol 714-F”, “Newcol 723”, “Newcol 2307”, and “Newcol 2303” (which are all manufactured by NIPPON NYUKAZAI CO., LTD.), “Pionin D-1107-S”, “Pionin D-1007”, “Pionin D-1106-DIR”, “Newkalgen TG310”, “Pionin D-6105-W”, “Pionin D-6112”, and “Pionin D-6512” (which are all manufactured by TAKEMOTO OIL & FAT Co., Ltd.), “SURFYNOL 420” “SURFYNOL 440”, “SURFYNOL 465”, and “SURFYNOL 2502” (which are all manufactured by Air Products and Chemicals, Inc.), “MEGAFACE F171”, “MEGAFACE F172”, “MEGAFACE F173”, “MEGAFACE F176”, “MEGAFACE F177”, “MEGAFACE F141”, “MEGAFACE F142”, “MEGAFACE F143”, “MEGAFACE F144”, “MEGAFACE R30”, “MEGAFACE F437”, “MEGAFACE F475”, “MEGAFACE F479”, “MEGAFACE F482”, “MEGAFACE F562”, “MEGAFACE F563”, “MEGAFACE F780”, “MEGAFACE R-40”, “MEGAFACE DS-21”, “MEGAFACE RS-56”, “MEGAFACE RS-90”, and “MEGAFACE RS-72-K” (which are all manufactured by DIC Corporation), “Fluorad FC430” and “Fluorad FC431” (which are all manufactured by Sumitomo 3M Limited), “AsahiGuard AG710”, “Surflon S-382”,“Surflon SC-101”, “Surflon SC-102”, “Surflon SC-103”, “Surflon SC-104”, “Surflon SC-105”, and “Surflon SC-106 (which are all manufactured by AGC Inc.), and “FTX-218” and “NBX-15” (manufactured by NEOS Co., Ltd.).

### [Method for Preparing Composition for Forming Resist Underlayer Film]

The composition for forming a resist underlayer film can be prepared by mixing the compound [A], the solvent [B] and, as necessary, an optional component in a prescribed ratio and preferably filtering the resulting mixture through a membrane filter having a pore size of 0.5 μm or less, or the like.

### <Cleaning Liquid>

The cleaning liquid contains an organic acid [E]. Furthermore, the cleaning liquid preferably contains an organic solvent (hereinafter also referred to as “organic solvent [G]”). The cleaning liquid may contain water as another solvent other than the organic solvent. The cleaning liquid may contain other optional components to the extent that the effects of the present invention are not impaired. Examples of the optional components include the components exemplified as the ligand represented by L in the formula (a).

### [Organic Acid [E]]

The organic acid [E] is a non-polymeric organic acid. The addition of organic acid [E] to the cleaning liquid facilitates removal of the film formed on the periphery of the substrate. The lower limit of the molecular weight of the organic acid [E] is preferably 45, more preferably 55, even more preferably 65, and especially preferably 70 in terms of drainage stability. The upper limit of the molecular weight of the organic acid [E] preferably 500, more preferably 400, and even more preferably 300. One or more of the organic acid [E] can be used alone or in combination. As organic acid [E], the organic acid [a] used in the synthesis of the compound [A] can be suitably employed.

Carboxylic acids are preferred as organic acid [E]. More specifically, its examples include carboxylic acids consisting of an aliphatic saturated hydrocarbon group and/or an aromatic hydrocarbon group and a carboxy group, such as formic acid, acetic acid, propionic acid, butanoic acid (butyric acid), isobutanoic acid (isobutyric acid), pentanoic acid, hexanoic acid, 2-ethylhexanoic acid, cyclohexanecarboxylic acid, cyclohexylacetic acid, 1-adamantanecarboxylic acid, benzoic acid, phenylacetic acid, and the like, monocarboxylic acids containing fluorine atoms such as difluoroacetic acid, trifluoroacetic acid, pentafluoropropanoic acid, heptafluorobutanoic acid, fluorophenylacetic acid, and difluorobenzoic acid,
monocarboxylic acids containing heteroatom-containing groups other than fluorine atoms in parts other than the carboxylic group such as 10-hydroxydecanoic acid, 5-oxohexanoic acid, 3-methoxycyclohexanecarboxylic acid, camphor carboxylic acid, dinitrobenzoic acid, nitrophenyl acetic acid, lactic acid, glycolic acid, glyceric acid, salicylic acid, anisic acid, gallic acid, and furan carboxylic acid,
unsaturated monocarboxylic acids such as acrylic acid, methacrylic acid, crotonic acid, isocrotonic acid, 3-butenic acid, angelica acid, tigrinic acid, 4-pentenoic acid, silicic acid, sorbic acid, propiolic acid, and 2-butyric acid,
polycarboxylic acids consisting of a single bond, an aliphatic saturated hydrocarbon group and/or an aromatic hydrocarbon group and multiple carboxy groups, such as oxalic acid, malonic acid, succinic acid, glutaric acid, adipic acid, dodecanedicarboxylic acid, propane tricarboxylic acid, butane tetracarboxylic acid, cyclohexane hexacarboxylic acid, 1,4-naphthalenedicarboxylic acid, phthalic acid, isophthalic acid, terephthalic acid, trimeritic acid, pyromellitic acid, 1,2,3,4-cyclobutane tetracarboxylic acid,
partial esters of the polycarboxylic acids,
polycarboxylic acids containing fluorine atoms such as difluoromalonic acid, tetrafluorophthalic acid, and hexafluoroglutaric acid,
polycarboxylic acids containing heteroatoms other than fluorine atoms in parts other than the carboxylic group, such as tartaric acid, citric acid, malic acid, tartronic acid, diglycolic acid, and iminodiacetic acid,
unsaturated polycarboxylic acids such as maleic acid, fumaric acid, and aconitic acid are examples.

The organic acid [E] is preferably an unsaturated carboxylic acid, more preferably an unsaturated monocarboxylic acid, and at least one selected from the group consisting of acrylic acid, methacrylic acid, crotonic acid, isocrotonic acid and 3-butenic acid.

The lower limit of the content of the organic acid [E] in all components contained in the cleaning liquid is preferably 0.5% by mass, more preferably 1% by mass, even more preferably 2% by mass, and particularly preferably 3% by mass. The upper limit of the content is preferably 80% by mass, more preferably 70% by mass, even more preferably 65% by mass, and particularly preferably 60% by mass. By setting the content of the organic acid [E] within the above range, cleanability and drainage stability can be further improved.

### [Organic Solvent[G]]

As the organic solvent [G] that is preferably contained in the cleaning liquid, the organic solvents exemplified as the solvent [B] that is contained in the composition for forming a resist underlayer film can be used.

The organic solvent [G] is preferably at least one selected from the group consisting of the ketone-based solvents and the ester-based solvents, and the chain ketone solvent, the acetic acid monoester solvent, the polyhydric alcohol partial ether carboxylate solvent or a combination thereof is more preferable, and butyl acetate, propylene glycol monomethyl ether acetate, 2-heptanone, or a combination of these is further preferable.

The lower limit of the content of organic solvent [G] in the total amount of the organic acid [E] and organic solvent [G] is 20% by mass, 30% by mass is more preferred, and 35% by mass is more preferred. The upper limit of the content is 99% by mass is preferred, 98% by mass is more preferred, and 95% by mass is more preferred.

### [Method for Preparing Cleaning Liquid]

The cleaning liquid can be prepared by mixing the organic acid [E] and, if necessary, the organic solvent [G] and optional components in predetermined proportions, and preferably filtering the resulting mixture through a membrane filter with a pore diameter of 0.5 μm or less.

### [Applying Step]

In the applying step, the composition for forming a resist underlayer film formation is applied directly or indirectly to a substrate. The method of the application of the composition for forming a resist underlayer film is not particularly limited, and the application can be performed by an appropriate method such as spin coating, cast coating, or roll coating. As a result, a coating film is formed, and volatilization of the solvent [B] or the like occurs, so that a resist underlayer film is formed.

Examples of the substrate include metal or metalloid substrates such as a silicon substrate, an aluminum substrate, a nickel substrate, a chromium substrate, a molybdenum substrate, a tungsten substrate, a copper substrate, a tantalum substrate, and a titanium substrate. Among them, a silicon substrate is preferred. The substrate may be a substrate having a silicon nitride film, an alumina film, a silicon dioxide film, a tantalum nitride film, or a titanium nitride film formed thereon.

The lower limit of the average thickness of the resist underlayer film to be formed is preferably 3 nm, more preferably 5 nm, and still more preferably 10 nm. The upper limit of the average thickness is preferably 500 nm, more preferably 200 nm, and even more preferably 60 nm. The average thickness is measured as described in Examples.

The method for manufacturing a semiconductor substrate preferably further includes heating a coating film formed in the applying step (hereinafter also referred to as a “heating step”). The formation of the resist underlayer film is promoted by heating the coating film. More specifically, volatilization or the like of the solvent [B] is promoted by heating the coating film.

The heating of the coating film is usually performed in the atmosphere but may be performed in a nitrogen atmosphere. The lower limit of a heating temperature is preferably 150° C., and more preferably 200° C. The upper limit of the temperature is preferably 600° C., more preferably 500° C. The lower limit of a heating time is preferably 15 seconds, more preferably 30 seconds. The upper limit of the time is preferably 1,200 seconds, and more preferably 600 seconds.

### [Organic Underlayer Film Forming Step]

In this step, before the resist pattern forming step, an organic underlayer film is formed directly or indirectly on the substrate having the resist underlayer film formed through the applying step.

The organic underlayer film can be formed by applying a composition for forming an organic underlayer film. One example of a method for forming an organic underlayer film by coating with a composition for forming an organic underlayer film is a method in which the substrate having a resist underlayer film is directly or indirectly coated with a composition for forming an organic underlayer film, and a formed coating film is cured by heating or lithographic exposure. As the composition for forming an organic underlayer film, for example, “HM8006” manufactured by JSR Corporation can be used. Various conditions for heating or exposure can be appropriately determined according to the type of the composition for forming an organic underlayer film to be used.

### [Silicon-Containing Film Forming Step]

In this step, before the resist pattern forming step, a silicon-containing film is formed directly or indirectly on the substrate having the resist underlayer film formed through the applying step.

One example of a case where a silicon-containing film is indirectly formed on the substrate having a resist underlayer film is a case where a surface modification film for the resist underlayer film is formed on the resist underlayer film.

The silicon-containing film can be formed by, for example, coating with a composition for forming a silicon-containing film, chemical vapor deposition (CVD), or atomic layer deposition (ALD). Examples of a method for forming a silicon-containing film by coating a composition for forming a silicon-containing film include a method including curing, by lithographic exposure and/or heating, a coating film formed by applying the composition for forming a silicon-containing film directly or indirectly to the resist underlayer film. As a commercially-available product of the composition for forming a silicon-containing film, for example, “NFC SOG01”, “NFC SOGO4”, “NFC SOG080” (which are all manufactured by JSR Corporation), or the like can be used. By chemical vapor deposition (CVD) or atomic layer deposition (ALD), a silicon oxide film, a silicon nitride film, a silicon oxynitride film, or an amorphous silicon film can be formed.

### [Cleaning Step]

In this step, the periphery of the substrate is cleaned with a cleaning liquid. The above-mentioned cleaning liquid can be suitably used as the cleaning liquid.

The cleaning method is not limited, and any known method can be used. Typically, first, the substrate on which various films are formed is rotated at a predetermined speed. Next, the cleaning liquid discharge nozzle is moved at a predetermined speed from the outer edge of the rotating substrate toward the center of the substrate while discharging the cleaning liquid from the nozzle. When the cleaning liquid discharge nozzle has traveled a predetermined distance, the movement is stopped and the cleaning liquid is further discharged for a predetermined period of time. The cleaning is then completed by stopping the discharge of the cleaning liquid from the cleaning liquid discharge nozzle and drying the substrate as necessary. The substrate rotation speed, the amount of cleaning liquid dispensed per unit time, the moving speed and distance of the cleaning liquid discharge nozzle, and the time for discharging the cleaning liquid after the nozzle stops moving can be set appropriately according to the substrate size, the number, type, and thickness of the formed films, and the cleaning area.

After applying the composition for forming a resist underlayer film to the substrate, the cleaning step can be performed with or without the heating step. When the cleaning step is performed without the heating step after the coating step, it is preferable to perform the heating step after the cleaning step.

### [Resist Pattern Forming Step]

After the cleaning step, in this step, a resist pattern is formed directly or indirectly on the resist underlayer film. Examples of a method for performing this step include a method using a resist composition, a method using nanoimprinting, and a method using a self-assembly composition. One example of a case where a resist pattern is indirectly formed on the resist underlayer film is a case where, when the method for manufacturing a semiconductor substrate includes the silicon-containing film forming step, a resist pattern is formed on the silicon-containing film.

Specifically, the method using a resist composition is performed by applying a resist composition in such a manner that a resist film to be formed has a predetermined thickness and then volatilizing a solvent in a coating film optionally by pre-baking to form a resist film.

Examples of the resist composition include a positive or negative chemically amplified resist composition containing a radiation sensitive acid generating agent, a positive resist composition containing an alkali-soluble resin and a quinonediazide-based photosensitizer, and a negative resist composition containing an alkali-soluble resin and a crosslinking agent. It should be noted that in this step, a commercially-available resist composition may directly be used.

Then, the formed resist film is subjected to exposure to light by selective irradiation with radiation. Radiation used for lithographic exposure can appropriately be selected depending on the type of radiation sensitive acid generating agent used in the resist composition, and examples thereof include electromagnetic rays such as visible rays, ultraviolet rays, far-ultraviolet, X rays, and γ rays and corpuscular rays such as electron rays, molecular rays, and ion beams. Among them, far-ultraviolet is preferred, KrF excimer laser light (248 nm), ArF excimer laser light (193 nm), F₂ excimer laser light (wavelength: 157 nm), Kr₂ excimer laser light (wavelength: 147 nm), ArKr excimer laser light (wavelength: 134 nm), or extreme ultraviolet (wavelength: 13.5 nm, hereinafter also referred to as “EUV”) is more preferred, and KrF excimer laser light, ArF excimer laser light, or EUV is even more preferred.

After the exposure to light, post-baking may be performed to improve resolution, pattern profile, developability, etc. The temperature and time of the post-baking may be appropriately determined according to the type or the like of the resist composition to be used.

Then, the exposed resist film is developed with a developer to form a resist pattern. This development may be either alkaline development or organic solvent development. Examples of the developer for alkaline development include basic aqueous solutions of ammonia, triethanolamine, tetramethylammonium hydroxide (TMAH), and tetraethylammonium hydroxide. To these basic aqueous solutions, for example, a water-soluble organic solvent such as an alcohol, e.g., methanol or ethanol, or a surfactant may be added in an appropriate amount. Examples of the developer for organic solvent development include various organic solvents mentioned above as examples of the solvent [B] contained in the composition.

After the development with a developer, a prescribed resist pattern is formed through washing and drying.

### [Etching Step]

In this step, a pattern is formed to the resist underlayer film by etching using the resist pattern as a mask. The number of times of etching may be once or twice or more, that is, etching may sequentially be performed using a pattern obtained by etching as a mask. However, from the viewpoint of obtaining a pattern having a further superior shape, etching is preferably performed twice or more. When performed a plurality of times, etching is performed to the silicon-containing film, the organic underlayer film, the resist underlayer film, and the substrate sequentially in order. Examples of an etching method include dry etching and wet etching. Among them, dry etching is preferred from the viewpoint of achieving a further superior pattern shape of the substrate. The dry etching uses, for example, gas plasma such as oxygen plasma. As a result of the etching, a semiconductor substrate having a prescribed pattern is obtained.

The dry etching can be performed using, for example, a known dry etching device. An etching gas used for the dry etching can appropriately be selected depending on, for example, a mask pattern or the elemental composition of a film to be etched, and examples thereof include a fluorine-based gas such as CHF₃, CF₄, C₂F₆, C₃F₃, or SF₆, a chlorine-based gas such as Cl₂ or BCl₃, an oxygen-based gas such as O₂, O₃, or H₂O, a reductive gas such as H₂, CO, CO₂, CH₄, C₂H₂, C₂H₄, C₂H₆, C₃H₄, C₃H₆, C₃Hs, HF, HI, HBr, HCl, NO, and an inert gas such as He, N₂, or Ar. These gases can also be used in admixture. When the substrate is etched using the pattern of the resist underlayer film as a mask, a fluorine-based gas is usually used.

### <Method for Forming Resist Underlayer Film>

The method for forming a resist underlayer film includes a step of applying a composition for forming a resist underlayer film directly or indirectly to a substrate. As the composition for forming a resist underlayer film, the composition for forming a resist underlayer film to be used in the above-described method for manufacturing a semiconductor substrate can be suitably employed. As the applying step, the applying step of the above-described method for manufacturing a semiconductor substrate can be suitably employed.

### <<Cleaning Liquid>>

The cleaning liquid contains an organic acid [E]. Furthermore, the cleaning liquid preferably contains an organic solvent. The cleaning liquid may contain water as another solvent other than the organic solvent. As such a cleaning liquid, the cleaning liquid used in the above-mentioned method for manufacturing a semiconductor substrate can be suitably employed.

### EXAMPLES

Hereinafter, Examples are described. The following Examples merely illustrate typical Examples of the present disclosure, and the Examples should not be construed to narrow the scope of the present invention.

A concentration of the components other than the solvent in the mixture containing the compound [A] in the present example, a weight-average molecular weight (Mw) of the hydrolysis-condensate in the mixture containing the compound [A], and an average thickness of the film were measured by the following methods.

[Concentration of Components Other than Solvent in Mixture Containing Compound [A] ]

By firing 0.5 g of a mixture containing the compound [A] at 250° C. for 30 minutes, measuring a mass of the residue thus obtained, and dividing the mass of the residue by the mass of the solution containing the compound [A], the concentration (% by mass) of the components other than the solvent in the mixture containing the compound [A] was calculated.

### [Weight-Average Molecular Weight (Mw)]

The weight-average molecular weight was measured by gel permeation chromatography (detector: differential refractometer) with monodisperse polystyrene standards using GPC columns (“AWM-H” x 2, “AW-H” x 1, and “AW2500” x 2) manufactured by Tosoh Corporation under the analysis conditions specified by flow rate: 0.3 mL/min, elution solvent: mixture of N,N-dimethylacetamide with LiBr (30 mM) and citric acid (30 mM), and column temperature: 40° C.

### [Average Thickness of Resist Underlayer Film]

The average thickness of a resist underlayer film was determined by measuring film thicknesses at arbitrary nine points at intervals of 5 cm including the center of the resist underlayer film formed on a silicon wafer, using a spectroscopic ellipsometer (“M2000D” available from J. A. WOOLLAM Co.) and calculating the average value of the film thicknesses.

<Synthesis of compound [A]>

The compound [m], the compound [x], the solvent [d], and the solvent [B] used for the synthesis of the compound [A] are listed below. In the following synthesis examples, unless otherwise specified, “parts by mass” means a value taken when the mass of the compound [m] used is 100 parts by mass. In addition, the “molar ratio” means a value taken when the amount of the compound [m] used is 1. The concentrations (% by mass) of components other than the solvent in the mixture containing the compound [A] are also shown in Table 1. In Table 1, “-” indicates that the corresponding component was not used.

The following compounds were used as the compound [m].
m-1: Tetra-n-propoxyzirconium(IV)
m-2: Tetra-n-butoxyzirconium(IV)
m-3: Tetra-n-propoxyhafnium(IV)
m-4: Tetraisopropoxytitanium(IV)
m-5: Pentaethoxytantalum(V)
m-6: Tetraisopropoxys tin (IV).

The following compounds were used as the compound [x].
x-1: Propionic acid
x-2: Butyric acid
x-3: Isobutyric acid
x-4: Methacrylic acid
x-5: 2-Ethylhexanoic acid
x-6: Acetylacetone
x-7: Diethanolamine

The following compounds were used as the solvent [d].
d-1: n-Propyl alcohol
d-2: Ethanol
d-3: 1-Butanol
d-4: Isopropanol

As the solvent [B], the following compounds were used.
B-1: Propylene glycol monomethyl ether acetate
B-2: Propylene glycol monoethyl ether

### [Synthesis Example 1-1] (Synthesis of compound [A] (A-1))

The compound (m-1) and the solvent (d-1) (40 parts by mass) were charged into a reaction vessel under a nitrogen atmosphere. In the reaction vessel, the compound (x-1) (molar ratio: 5) was added dropwise over 20 minutes with stirring at 50° C. The reaction was then carried out at 80° C. for 3 hours. After the completion of the reaction, the inside of the reaction vessel was cooled to 30° C. or lower. The precipitate obtained via the cooling was collected by filtration, washed with n-hexane (100 parts by mass), and then vacuum-dried, affording compound (A-1).

### [Synthesis Example 1-2] (Synthesis of Compound [A] (A-2))

The compound (m-1) and the solvent (d-1) (200 parts by mass) were charged into a reaction vessel under a nitrogen atmosphere. In the reaction vessel, the compound (x-2) (molar ratio: 5) was added dropwise over 20 minutes with stirring at 50° C. The reaction was then carried out at 80° C. for 3 hours. After the completion of the reaction, the inside of the reaction vessel was cooled to 30° C. or lower. After 900 parts by mass of the solvent (B-1) was added to the cooled reaction solution, the solvent (d-1), the alcohol generated via the reaction, and the excess solvent (B-1) were removed using an evaporator, affording a mixture containing compound (A-2). The concentration of the components other than the solvent in the mixture containing the compound [A] (A-2) was 14% by mass.

### [Synthesis Examples 1-10 and 1-14] (Synthesis of Compounds [A](A-10) and (A-14))

Compounds [A] (A-10) and (A-14) were obtained in the same manner as in Synthesis Example 1-1 except that the compound [m], the compound [x] and the solvent [d] of the type and use amount given in the following Table 1 were used.

### [Synthesis Examples 1-3 to 1-9, 1-11 to 1-13 and 1-17] (Synthesis of Compounds [A] (A-3) to (A-9), (A-11) to (A-13) and (A-17))

Mixtures containing compounds [A] (A-3) to (A-9), (A-11) to (A-13) and (A-17) were obtained in the same manner as in Synthesis Example 1-2 except that the compound [m], the compound [x], the solvent [d], and the solvent [B] of the type and use amount given in the following Table 1 were used.

### [Synthesis Example 1-15] (Synthesis of Compound [A] (A-15))

The compound (m-4) was charged into a reaction vessel under a nitrogen atmosphere. In the reaction vessel, the compound (x-6) (molar ratio: 2) was added dropwise over 30 minutes with stirring at room temperature (25° C. to 30° C.). The reaction was then carried out at 60° C. for 2 hours. After the completion of the reaction, the inside of the reaction vessel was cooled to 30° C. or lower. The cooled reaction solution was diluted with the solvent (d-4) (900 parts by mass). In the reaction vessel, water (molar ratio: 2) was added dropwise over 10 minutes with stirring at room temperature (25° C. to 30° C.). A hydrolysis-condensation reaction was then carried out at 60° C. for 2 hours. After the completion of the hydrolysis-condensation reaction, the inside of the reaction vessel was cooled to 30° C. or lower. After 1,000 parts by mass of the solvent (B-2) was added to the cooled reaction solution, water, isopropanol, the alcohol generated via the reaction, and the excess solvent (B-2) were removed using an evaporator, affording a mixture containing compound (A-15). The concentration of the components other than the solvent in the mixture containing the compound [A](A-15) was 13% by mass.

### [Synthesis Example 1-16] (Synthesis of Compound [A] (A-16))

A mixture containing compound [A] (A-16) was obtained in the same manner as in Synthesis Example 1-15 except that the compound [m], the compound [x], the solvent [d], and the solvent [B] of the type and use amount given in the following Table 1 were used.

TABLE 1

| | | | | | | | | Concentration of |
|---|---|---|---|---|---|---|---|---|
| | | | | | | | | components other |
| | | | | | | | | than the solvent in |
| | | Compound [m] | | Compound [x] | | Solvent | Solvent | a mixture containing |
| | Compound | | Molar | | Molar | [d] | [B] | the compound [A] |
| | [A] | Type | ratio | Type | ratio | Type | Type | (% by mass) |
| Synthesis | A-1 | m-1 | 1 | x-1 | 5 | d-1 | — | 100 |
| example 1-1 | | | | | | | | |
| Synthesis | A-2 | m-1 | 1 | x-2 | 5 | d-1 | B-1 | 14 |
| example 1-2 | | | | | | | | |
| Synthesis | A-3 | m-1 | 1 | x-3 | 5 | d-1 | B-1 | 14 |
| example 1-3 | | | | | | | | |
| Synthesis | A-4 | m-1 | 1 | x-4 | 1 | d-1 | B-1 | 13 |
| example 1-4 | | | | | | | | |
| Synthesis | A-5 | m-1 | 1 | x-4 | 2 | d-1 | B-1 | 13 |
| example 1-5 | | | | | | | | |
| Synthesis | A-6 | m-1 | 1 | x-4 | 3 | d-1 | B-1 | 13 |
| example 1-6 | | | | | | | | |
| Synthesis | A-7 | m-1 | 1 | x-4 | 5 | d-1 | B-1 | 20 |
| example 1-7 | | | | | | | | |
| Synthesis | A-8 | m-1 | 1 | x-5 | 5 | d-1 | B-1 | 20 |
| example 1-8 | | | | | | | | |
| Synthesis | A-9 | m-2 | 1 | x-4 | 5 | d-3 | B-1 | 20 |
| example 1-9 | | | | | | | | |
| Synthesis | A-10 | m-3 | 1 | x-4 | 5 | d-1 | — | 100 |
| example 1-10 | | | | | | | | |
| Synthesis | A-11 | m-4 | 1 | x-3 | 5 | d-4 | B-1 | 13 |
| example 1-11 | | | | | | | | |
| Synthesis | A-12 | m-5 | 1 | x-3 | 6 | d-2 | B-1 | 13 |
| example 1-12 | | | | | | | | |
| Synthesis | A-13 | m-2 | 1 | x-6 | 1 | d-3 | B-2 | 14 |
| example 1-13 | | | | | | | | |
| Synthesis | A-14 | m-2 | 1 | x-6 | 4 | d-3 | — | 100 |
| example 1-14 | | | | | | | | |
| Synthesis | A-15 | m-4 | 1 | x-6 | 2 | d-4 | B-2 | 13 |
| example 1-15 | | | | | | | | |
| Synthesis | A-16 | m-4 | 1 | x-7 | 2 | d-4 | B-1 | 20 |
| example 1-16 | | | | | | | | |
| Synthesis | A-17 | m-6 | 1 | x-4 | 5 | d-4 | B-1 | 20 |
| example 1-17 | | | | | | | | |

### <Preparation of Composition>

The compounds [A], the solvent [B], and other optional components [F] are described below.

The compounds (A-1) to (A-17) synthesized above were used as the compound [A].

In addition to (B-1) and (B-2) used for the synthesis of the compound [A], the following compounds were used as the solvent [B].
B-3: Cyclohexanone
B-4: Mesitylene
B-5: Butyl acetate
B-6: 2-heptanone

The following compound was used as other optional ingredients [F].

### F-1: 4-Methoxyphenol

### [Example 1-1] Preparation of Composition (J-1)

As shown in the following Table 2 and 90 parts by mass of (B-3) as the solvent [B] were mixed per 10 parts by mass of the compound [A] (A-1). The resulting solution was filtered through a polytetrafluoroethylene (PTFE) filter having a pore size of 0.2 μm to prepare composition (J-1). “-” for other optional components [F] in the following Table 2 indicates that the other optional components [F] were not used. The same applies hereinafter.

### [Example 1-2] Preparation of Composition (J-2)

As shown in the following Table 2, a mixture containing the compound [A] (A-2) and (C-1) as the solvent [B] were mixed such that the amount of the solvent [B] (including the solvent [B] contained in the mixture containing the compound [A]) was 90 parts by mass per 10 parts by mass of the components other than the solvent in the compound [A] (A-2). The resulting solution was filtered through a polytetrafluoroethylene (PTFE) filter having a pore size of 0.2 μm to prepare composition (J-2).

### [Examples 1-3 to 1-29] Preparation of Compositions (J-3) to (J-29)

Compositions (J-3) to (J-29) were prepared in the same manner as in Example 1-1 or Example 1-2 except that the type and content of each component were set as shown in the following Table 2. In Table 2, “-” indicates that the corresponding component was not used.

TABLE 2

| | | Components other | | | | | |
|---|---|---|---|---|---|---|---|
| | | than the solvent in | | | | | |
| | | the [A] compound | | | | | |
| | | or a mixture | | | | | |
| | | containing the | | | | Other optional | |
| | | [A] compound | | Solvent[B] | | components [F] | |
| | | | Content | | Content | | Content |
| | Composition | | (parts by | | (parts by | | (parts by |
| | (J) | Type | mass) | Type | mass) | Type | mass) |
| Example 1-1 | J-1 | A-1 | 10 | B-3 | 90 | — | — |
| Example 1-2 | J-2 | A-2 | 10 | B-1 | 90 | — | — |
| Example 1-3 | J-3 | A-3 | 10 | B-1 | 90 | — | — |
| Example 1-4 | J-4 | A-4 | 10 | B-1 | 89.995 | F-1 | 0.005 |
| Example 1-5 | J-5 | A-5 | 10 | B-1 | 89.995 | F-1 | 0.005 |
| Example 1-6 | J-6 | A-6 | 10 | B-1 | 89.995 | F-1 | 0.005 |
| Example 1-7 | J-7 | A-7 | 10 | B-1 | 89.995 | F-1 | 0.005 |
| Example 1-8 | J-8 | A-7 | 10 | B-1/B-5 | 72/17.995 | F-1 | 0.005 |
| Example 1-9 | J-9 | A-7 | 10 | B-1/B-5 | 54/35.995 | F-1 | 0.005 |
| Example 1-10 | J-10 | A-7 | 10 | B-1/B-5 | 36/53.995 | F-1 | 0.005 |
| Example 1-11 | J-11 | A-8 | 10 | B-1 | 90 | — | — |
| Example 1-12 | J-12 | A-8 | 10 | B-1/B-5 | 72/17.995 | — | — |
| Example 1-13 | J-13 | A-8 | 10 | B-1/B-5 | 54/35.995 | — | — |
| Example 1-14 | J-14 | A-8 | 10 | B-1/B-5 | 36/53.995 | — | — |
| Example 1-15 | J-15 | A-9 | 10 | B-1 | 89.995 | F-1 | 0.005 |
| Example 1-16 | J-16 | A-9 | 10 | B-1/B-6 | 72/17.995 | F-1 | 0.005 |
| Example 1-17 | J-17 | A-9 | 10 | B-1/B-6 | 54/35.995 | F-1 | 0.005 |
| Example 1-18 | J-18 | A-9 | 10 | B-1/B-6 | 36/53.995 | F-1 | 0.005 |
| Example 1-19 | J-19 | A-10 | 10 | B-1 | 89.995 | F-1 | 0.005 |
| Example 1-20 | J-20 | A-11 | 10 | B-1 | 89.995 | F-1 | 0.005 |
| Example 1-21 | J-21 | A-12 | 10 | B-1 | 89.995 | F-1 | 0.005 |
| Example 1-22 | J-22 | A-13 | 10 | B-2 | 90 | — | — |
| Example 1-23 | J-23 | A-14 | 10 | B-4 | 90 | — | — |
| Example 1-24 | J-24 | A-14 | 10 | B-1/B-6 | 72/17.995 | — | — |
| Example 1-25 | J-25 | A-14 | 10 | B-1/B-6 | 54/35.995 | — | — |
| Example 1-26 | J-26 | A-14 | 10 | B-1/B-6 | 36/53.995 | — | — |
| Example 1-27 | J-27 | A-15 | 10 | B-2 | 90 | — | — |
| Example 1-28 | J-28 | A-16 | 10 | B-1 | 90 | — | — |
| Example 1-29 | J-29 | A-17 | 10 | B-1 | 90 | — | — |

### <Preparation of Cleaning Liquid>

The organic acid [E], the organic solvent [G], and other solvents other than the organic solvent [G] used in the preparation of the cleaning liquid are listed below.

The following compounds (E-1) to (E-10) were used as the organic acid [E].
E-1: Formic acid
E-2: Acetic acid
E-3: Propionic acid
E-4: Acrylic acid
E-5: Butyric acid
E-6: Isobutyric acid
E-7: Methacrylic acid
E-8: Crotonic acid
E-9: 2-Ethylhexanoic acid
E-10: Oxalic acid

The following compounds (G-1) to (G-4) and (G-6) to (G-7) were used as the organic solvent [G], and (G-5) was used as other solvents other than the organic solvent [G].
G-1: Propylene glycol monomethyl ether acetate
G-2: Butyl acetate
G-3: 2-heptanone
G-4: Propylene glycol monomethyl ether
G-5: Water
G-6: Dimethyl sulfoxide
G-7: Sulfolane

### [Example 2-1] Preparation of Cleaning Liquid (K-1)

As shown in Table 3 below, 80 parts by mass of the organic solvent [G] (G-1) were mixed with 20 parts by mass of (E-1) as the organic acid [E]. The resulting solution was filtered through a polytetrafluoroethylene (PTFE) filter with a pore diameter of 0.2 μm to prepare the cleaning liquid (K-1). In Table 3 below, “-” indicates that the corresponding component was not used.

### [Examples 2-2 to 2-29 and Comparative Example 1-1] Preparation of Cleaning Liquids (K-2) to (K-29) and (k-1)

Cleaning liquids (K-2) to (K-29) and (k-1) were prepared in the same manner as in Example 2-1, except that the type and content of each component were as shown in Table 3 below.

TABLE 3

| | | Organic solvent [G] | | | |
|---|---|---|---|---|---|
| | | and other solvent | | Organic acid [E] | |
| | Cleaning | | Content | | Content |
| | liquid | | (parts by | | (parts by |
| | (K) | Type | mass) | Type | mass) |
| Example 2-1 | K-1 | G-1 | 80 | E-1 | 20 |
| Example 2-2 | K-2 | G-1 | 80 | E-2 | 20 |
| Example 2-3 | K-3 | G-1 | 80 | E-3 | 20 |
| Example 2-4 | K-4 | G-1 | 80 | E-4 | 20 |
| Example 2-5 | K-5 | G-1 | 80 | E-5 | 20 |
| Example 2-6 | K-6 | G-1 | 80 | E-6 | 20 |
| Example 2-7 | K-7 | G-1 | 80 | E-7 | 20 |
| Example 2-8 | K-8 | G-1 | 80 | E-8 | 20 |
| Example 2-9 | K-9 | G-1 | 80 | E-9 | 20 |
| Example 2-10 | K-10 | G-1 | 98 | E-4 | 2 |
| Example 2-11 | K-11 | G-1 | 95 | E-4 | 5 |
| Example 2-12 | K-12 | G-1 | 90 | E-4 | 10 |
| Example 2-13 | K-13 | G-1 | 70 | E-4 | 30 |
| Example 2-14 | K-14 | G-1 | 60 | E-4 | 40 |
| Example 2-15 | K-15 | G-1 | 50 | E-4 | 50 |
| Example 2-16 | K-16 | G-1 | 30 | E-4 | 70 |
| Example 2-17 | K-17 | G-1 | 80 | E-4/E-5 | 10/10 |
| Example 2-18 | K-18 | G-2 | 80 | E-4 | 20 |
| Example 2-19 | K-19 | G-3 | 80 | E-4 | 20 |
| Example 2-20 | K-20 | G-1 | 90 | E-7 | 10 |
| Example 2-21 | K-21 | G-1 | 70 | E-7 | 30 |
| Example 2-22 | K-22 | G-1 | 90 | E-8 | 10 |
| Example 2-23 | K-23 | G-1 | 70 | E-8 | 30 |
| Example 2-24 | K-24 | G-1/G-4 | 24/56 | E-4 | 20 |
| Example 2-25 | K-25 | G-1/G-4/G-5 | 24/56/10 | E-4 | 10 |
| Example 2-26 | K-26 | G-4/G-5 | 80/10 | E-4 | 10 |
| Example 2-27 | K-27 | G-4/G-5 | 80/10 | E-10 | 10 |
| Example 2-28 | K-28 | G-6 | 90 | E-4 | 10 |
| Example 2-29 | K-29 | G-7 | 90 | E-10 | 10 |
| Comparative | k-1 | G-1 | 100 | — | — |
| example 1-1 | | | | | |

### <Evaluation>

Using each of the compositions prepared above, metal cleanability and drainage stability were evaluated according to the following methods. The evaluation results are given in the following Tables 4-1 and 4-2.

[Metal cleanability]

A composition prepared above was applied to a silicon wafer (substrate) by spin coating using a spin coater (“CLEAN TRACK ACT 8” available from Tokyo Electron Ltd.). Then, with rotation at 1500 rpm, while a cleaning liquid discharge nozzle was moved at a rate of 1 mm per second, a cleaning liquid (K) was discharged at a discharge rate of 2 ml per second to a position 2 mm away from the outer peripheral edge of the substrate toward the center of the substrate. After the cleaning liquid was discharged for 10 seconds at a discharge rate of 2 ml per second at the position 2 mm away from the outer peripheral edge of the substrate toward the center of the substrate, and the substrate was rotated at 1,500 rpm for 30 seconds. Next, this substrate was heated at 450° C. for 60 seconds, affording a substrate with a resist underlayer film having an average thickness of 30 nm. The top surface of the outer periphery (0.3 mm from the edge of the substrate) of the obtained evaluation substrate A was wetted with an acid, and all the liquid obtained by the wetting was collected and used as the test solution for measurement, and the metal content was measured by inductively coupled plasma mass spectrometry (ICP-MS).

Substrate B for evaluation with a resist underlayer film having an average thickness of 30 nm was obtained in the same manner as the procedure for obtaining the substrate A for evaluation, except that cleaning liquid (k-1) was used as the cleaning liquid. The top surface of the outer periphery (0.3 mm from the edge of the substrate) of the obtained evaluation substrate B was wetted with an acid, and all the liquid obtained by wetting was collected to be used as the test solution for measurement, and the metal content was measured by inductively coupled plasma mass spectrometry (ICP-MS).

Metal cleanability was evaluated as “A” if the amount of metal constituting the compound [A] detected from evaluation substrate A was less than 10% compared to that of evaluation substrate B, “B” if the amount was 10% or more and 50% or less, and “C” if the amount was 50% or more.

### [Drainage Stability]

Mixed solutions were prepared by mixing equal amounts of composition (J) and cleaning liquid (K), and were visually checked for precipitation and turbidity after standing each at 23° C. and −15° C. for one week. The drainage stability was evaluated as “A” if there was no precipitation or turbidity after one week at −15° C., and evaluated as “B” if there was no precipitation or turbidity after one week at 23° C., but precipitation or turbidity occurred after one week at −15° C.

TABLE 4-1

| | Composition | Cleaning | Metal | Drainage |
|---|---|---|---|---|
| | (J) | liquid (K) | cleanability | stability |
| Example 3-1 | J-1 | K-1 | A | B |
| Example 3-2 | J-1 | K-2 | A | B |
| Example 3-3 | J-1 | K-3 | A | A |
| Example 3-4 | J-1 | K-4 | A | A |
| Example 3-5 | J-1 | K-5 | A | A |
| Example 3-6 | J-1 | K-6 | A | A |
| Example 3-7 | J-1 | K-7 | A | A |
| Example 3-8 | J-1 | K-8 | A | A |
| Example 3-9 | J-1 | K-9 | A | A |
| Example 3-10 | J-1 | K-10 | B | A |
| Example 3-11 | J-1 | K-11 | A | A |
| Example 3-12 | J-1 | K-12 | A | A |
| Example 3-13 | J-1 | K-13 | A | A |
| Example 3-14 | J-1 | K-14 | A | A |
| Example 3-15 | J-1 | K-15 | A | A |
| Example 3-16 | J-1 | K-16 | B | A |
| Example 3-17 | J-1 | K-17 | A | A |
| Example 3-18 | J-1 | K-18 | A | A |
| Example 3-19 | J-1 | K-19 | A | A |
| Example 3-20 | J-1 | K-20 | A | A |
| Example 3-21 | J-1 | K-21 | A | A |
| Example 3-22 | J-1 | K-22 | A | A |
| Example 3-23 | J-1 | K-23 | A | A |
| Example 3-24 | J-1 | K-24 | A | A |
| Example 3-25 | J-1 | K-25 | A | A |
| Example 3-26 | J-1 | K-26 | A | A |
| Example 3-27 | J-1 | K-27 | A | A |
| Example 3-28 | J-1 | K-28 | A | A |
| Example 3-29 | J-1 | K-29 | A | A |
| Example 3-30 | J-19 | K-26 | A | A |
| Example 3-31 | J-19 | K-29 | A | A |
| Example 3-32 | J-20 | K-26 | A | A |
| Example 3-33 | J-20 | K-29 | A | A |
| Example 3-34 | J-21 | K-26 | A | A |
| Example 3-35 | J-21 | K-29 | A | A |
| Example 3-36 | J29 | K-26 | A | A |
| Example 3-37 | J29 | K-29 | A | A |
| Example 3-38 | J-2 | K-4 | A | A |
| Example 3-39 | J-3 | K-4 | A | A |
| Example 3-40 | J-4 | K-4 | A | A |
| Example 3-41 | J-5 | K-4 | A | A |
| Example 3-42 | J-6 | K-4 | A | A |
| Example 3-43 | J-7 | K-4 | A | A |
| Example 3-44 | J-8 | K-4 | A | A |
| Example 3-45 | J-9 | K-4 | A | A |
| Example 3-46 | J-10 | K-4 | A | A |
| Example 3-47 | J-11 | K-4 | A | A |
| Example 3-48 | J-12 | K-4 | A | A |
| Example 3-49 | J-13 | K-4 | A | A |
| Example 3-50 | J-14 | K-4 | A | A |
| Example 3-51 | J-15 | K-4 | A | A |
| Example 3-52 | J-16 | K-4 | A | A |
| Example 3-53 | J-17 | K-4 | A | A |

TABLE 4-2

| | Composition | Cleaning | Metal | Drainage |
|---|---|---|---|---|
| | (J) | liquid (K) | cleanability | stability |
| Example 3-54 | J-18 | K-4 | A | A |
| Example 3-55 | J-19 | K-4 | A | A |
| Example 3-56 | J-20 | K-4 | A | A |
| Example 3-57 | J-21 | K-4 | A | A |
| Example 3-58 | J-22 | K-4 | A | A |
| Example 3-59 | J-23 | K-4 | A | A |
| Example 3-60 | J-24 | K-4 | A | A |
| Example 3-61 | J-25 | K-4 | A | A |
| Example 3-62 | J-26 | K-4 | A | A |
| Example 3-63 | J-27 | K-4 | A | A |
| Example 3-64 | J-28 | K-4 | A | A |
| Example 3-65 | J-29 | K-4 | A | A |
| Example 3-66 | J-7 | K-7 | A | A |
| Example 3-67 | J-8 | K-7 | A | A |
| Example 3-68 | J-9 | K-7 | A | A |
| Example 3-69 | J-10 | K-7 | A | A |
| Example 3-70 | J-11 | K-7 | A | A |
| Example 3-71 | J-12 | K-7 | A | A |
| Example 3-72 | J-13 | K-7 | A | A |
| Example 3-73 | J-14 | K-7 | A | A |
| Example 3-74 | J-15 | K-7 | A | A |
| Example 3-75 | J-16 | K-7 | A | A |
| Example 3-76 | J-17 | K-7 | A | A |
| Example 3-77 | J-18 | K-7 | A | A |
| Example 3-78 | J-23 | K-7 | A | A |
| Example 3-79 | J-24 | K-7 | A | A |
| Example 3-80 | J-25 | K-7 | A | A |
| Example 3-81 | J-26 | K-7 | A | A |
| Example 3-82 | J-7 | K-8 | A | A |
| Example 3-83 | J-8 | K-8 | A | A |
| Example 3-84 | J-9 | K-8 | A | A |
| Example 3-85 | J-10 | K-8 | A | A |
| Example 3-86 | J-11 | K-8 | A | A |
| Example 3-87 | J-12 | K-8 | A | A |
| Example 3-88 | J-13 | K-8 | A | A |
| Example 3-89 | J-14 | K-8 | A | A |
| Example 3-90 | J-15 | K-8 | A | A |
| Example 3-91 | J-16 | K-8 | A | A |
| Example 3-92 | J-17 | K-8 | A | A |
| Example 3-93 | J-18 | K-8 | A | A |
| Example 3-94 | J-23 | K-8 | A | A |
| Example 3-95 | J-24 | K-8 | A | A |
| Example 3-96 | J-25 | K-8 | A | A |
| Example 3-97 | J-26 | K-8 | A | A |
| Comparative | J-1 | k-1 | — | A |
| Example 1 -1 | | | | |

As is clear from the results in Tables 4-1 and 4-2, both metal cleanability and drainage stability were superior in the examples compared to the comparative example.

According to the method for manufacturing a semiconductor substrate of the present disclosure, since a cleaning liquid with excellent cleanability and drainage stability is used to clean the periphery of the substrate, high-quality semiconductor substrates can be efficiently manufactured. According to the method of forming a resist underlayer film, since a cleaning liquid with excellent cleanability and drainage stability is used, a desired resist underlayer film can be efficiently formed. The cleaning liquid of the present disclosure excels in both cleanability and drainage stability. Therefore, they can be suitably used in the manufacture of semiconductor devices, and the like., which are expected to be further miniaturized in the future.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A method for manufacturing a semiconductor substrate, comprising:
applying a composition for forming a resist underlayer film directly or indirectly to a substrate to form a resist underlayer film;
cleaning a periphery of the substrate with a cleaning liquid; and
after cleaning the periphery, forming a resist pattern directly or indirectly on the resist underlayer film,
wherein the composition for forming a resist underlayer film comprises:
a metal compound; and
a solvent, and
wherein the cleaning liquid comprises an organic acid.

2. The method according to claim 1, further comprising
before forming the resist pattern,
forming an organic underlayer film directly or indirectly on the resist underlayer film.

3. The method according to claim 1, further comprising
before forming the resist pattern,
forming a silicon-containing film directly or indirectly on the resist underlayer film.

4. The method according to claim 1, wherein a metal atom in the metal compound belongs to Groups 3 to 16 of the periodic table.

5. The method according to claim 1, wherein a metal atom in the metal compound belongs to Group 4 of the periodic table.

6. The method according to claim 1, wherein the metal compound comprises an organic acid as a component other than a metal atom.

7. The method according to claim 1, wherein the cleaning liquid further comprises an organic solvent.

8. The method according to claim 1, wherein the organic solvent is at least one selected from the group consisting of a ketone-based solvent and an ester-based solvent.

9. The method according to claim 1, wherein the organic acid in the cleaning liquid is a carboxylic acid.

10. The method according to claim 1, wherein the organic acid in the cleaning liquid is an unsaturated carboxylic acid.

11. The method according to claim 9, wherein the carboxylic acid is at least one selected from the group consisting of acrylic acid, methacrylic acid, crotonic acid, isocrotonic acid and 3-butenic acid.

12. The method according to claim 1, wherein a content of the organic acid in the cleaning liquid is 3% by mass or more and 60% by mass or less relative to 100% by mass of the cleaning liquid.

13. A method of forming a resist underlayer film, comprising:
applying a composition for forming a resist underlayer film directly or indirectly to a substrate to form a resist underlayer film; and
cleaning a periphery of the substrate with a cleaning liquid,
wherein the composition for forming a resist underlayer film comprises:
a metal compound; and
a solvent, and
wherein the cleaning liquid comprises an organic acid.

14. A cleaning liquid comprising an organic acid,
wherein the cleaning liquid is suitable for a method for manufacturing a semiconductor substrate, the method comprising applying a composition for forming a resist underlayer film directly or indirectly to a substrate to form a resist underlayer film, and cleaning the periphery of the substrate with the cleaning liquid, and
wherein the composition for forming a resist underlayer film comprises:
a metal compound; and
a solvent.
